(19) United States
(12) Patent Application Publication
(10) Pub. No.: US 2026/0251985 A1
(43) Pub. Date: Aug. 27, 2026

(54) STAGE APPARATUS, SUBSTRATE PROCESSING APPARATUS, INFORMATION PROCESSING APPARATUS, INFORMATION PROCESSING METHOD, STORAGE MEDIUM, AND ARTICLE MANUFACTURING METHOD

(71) Applicant: CANON KABUSHIKI KAISHA, Tokyo (JP)

(72) Inventors: MAMORU KANEISHI, Tochigi (JP); MASAKI IMAI, Saitama (JP)

(21) Appl. No.: 19/648,989

(22) Filed: Apr. 15, 2026

Related U.S. Application Data
(63) Continuation of application No. PCT/JP2024/037149, filed on Oct. 18, 2024.

(30) Foreign Application Priority Data
Oct. 24, 2023 (JP) 2023-182845

(51) Int. Cl. G03F 7/00

(52) U.S. Cl. CPC G03F 7/70725; G03F 7/70358; G03F 7/70775

(57) ABSTRACT

A stage configured to move while holding a substrate and a control unit configured to control movement of the stage based on a driving profile are included. The driving profile is determined based on a first parameter that is a parameter related to movement of the stage in a first direction and a second parameter that is a parameter related to movement of the stage in a second direction determined based on the first parameter, and a moving distance of the stage in the first direction is longer than a moving distance in the second direction.

### CROSS-REFERENCE TO RELATED APPLICATIONS

This application is a Continuation of International Patent Application No. PCT/JP2024/037149, filed Oct. 18, 2024, which claims the benefit of Japanese Patent Application No. 2023-182845, filed Oct. 24, 2023, both of which are hereby incorporated by reference herein in their entirety.

### BACKGROUND

### Field of the Technology

The present disclosure relates to a stage apparatus, a substrate processing apparatus, an information processing apparatus, an information processing method, a storage medium, and an article manufacturing method.

### Description of the Related Art

In manufacturing processes for semiconductor devices, liquid crystal display devices, and the like, a stage apparatus is used to move a substrate to a desired position. Japanese Patent Laid-Open No. 2015-216326 describes calculating three target loci for a stage to move from an end of exposure to a start of next exposure and adopting the target locus that is feasible among the calculated target loci and minimizes a driving time of the stage.

Here, the stage is driven in two perpendicular directions (X-axis and Y-axis directions) on a plane on which a substrate is held to move the substrate to a desired position, and a stage velocity in a case where the stage is driven simultaneously in these two directions is a composite velocity of the velocities in the respective two directions. A maximum value (limit velocity) of the composite velocity is determined by a hardware configuration, so that it may not be possible to drive at the maximum velocity in each of the two directions due to this limitation.

### SUMMARY

The present disclosure is directed to the provision of a stage apparatus that is capable of shortening a driving time.

To achieve the above-described purpose, a stage apparatus as an aspect of the present disclosure includes a stage configured to move while holding a substrate, and a control unit configured to control movement of the stage based on a driving profile. The driving profile is determined based on a first parameter that is a parameter related to movement of the stage in a first direction and a second parameter that is a parameter related to movement of the stage in a second direction determined based on the first parameter, and a moving distance of the stage in the first direction is longer than a moving distance in the second direction.

Features of the present disclosure will become apparent from the following description of embodiments with reference to the attached drawings.

### BRIEF DESCRIPTION OF THE DRAWINGS

FIG. 1 is a schematic diagram illustrating a configuration of a substrate processing apparatus according to a first embodiment.

FIG. 2A is a schematic diagram illustrating a substrate being scanned for exposure.

FIG. 2B is a schematic diagram illustrating a substrate being scanned for exposure.

FIG. 3 is a diagram illustrating a driving profile of a substrate stage at the time of exposing an 84th shot area and an 85th shot area according to a conventional example.

FIG. 4 is a diagram illustrating a driving profile of a substrate stage at the time of exposing an 84th shot area and an 85th shot area according to the first embodiment.

FIG. 5 is a diagram illustrating a flowchart for determining a driving profile according to the first embodiment.

FIG. 6 is a diagram illustrating a driving profile of a substrate stage at the time of exposing an 84th shot area and an 85th shot area according to a second embodiment.

FIG. 7 is a diagram illustrating a driving profile of a substrate stage at the time of exposing an 84th shot area and an 85th shot area according to a third embodiment.

FIG. 8 is a diagram illustrating a driving profile of a substrate stage at the time of moving an 87th shot area to a target position and then moving an 8th shot area according to the conventional example.

FIG. 9 is a diagram illustrating a driving profile of a substrate stage at the time of moving an 87th shot area to a target position and then moving an 8th shot area according to a fourth embodiment.

FIG. 10 is a diagram illustrating a flowchart of a manufacturing method for an article according to a fifth embodiment.

### DESCRIPTION OF THE EMBODIMENTS

Embodiments of the present disclosure will be described below with reference to the drawings. The embodiments which will be described below do not restrict the present disclosure according to the claims. A plurality of features is described in the embodiments, but not all of the plurality of features is essential to the present disclosure, and the plurality of features may be optionally combined. Further, the same or similar configurations in the attached drawings are denoted by the same reference numerals, and redundant description will be omitted.

In the present specification and drawings, directions are basically indicated by an XYZ coordinate system in which the vertical direction is the Z direction, a horizontal plane perpendicular to the vertical direction is an XY plane, and axes are perpendicular to each other. However, in a case where an XYZ coordinate system is illustrated in each drawing, that coordinate system takes precedence.

A specific configuration will be described below in each embodiment.

### First Embodiment

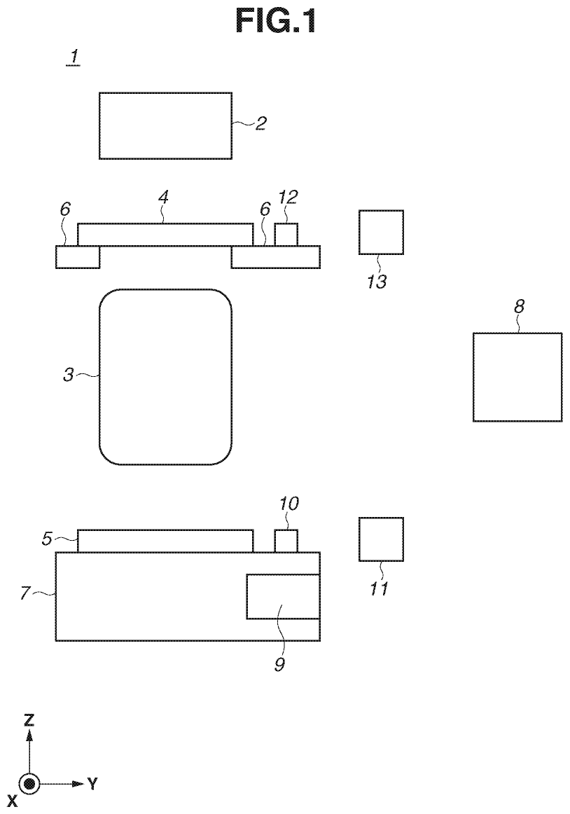

FIG. 1 is a schematic diagram illustrating a configuration of a substrate processing apparatus 1 according to the present embodiment. According to the present embodiment, the substrate processing apparatus 1 is a projection exposure apparatus that adopts a step and scan method to expose a pattern of an original plate (mask, reticle) onto a substrate via a projection optical system. However, the substrate processing apparatus 1 is not limited to a projection exposure apparatus. The substrate processing apparatus 1 may be, for example, a projection exposure apparatus adopting a step and repeat method. Alternatively, the substrate processing apparatus 1 may be a drawing apparatus that draws on a substrate using an electron beam, an ion beam, or the like to form a pattern on the substrate. Further, the substrate processing apparatus 1 may be another lithography apparatus (a substrate exposure apparatus), for example, an imprint apparatus that molds an imprint material on a substrate into a mold and forms a pattern on the substrate. Alternatively, the substrate processing apparatus 1 may be another apparatus that processes a substrate (e.g., a semiconductor wafer or a glass plate), such as an ion implantation apparatus, a development apparatus, an etching apparatus, a film forming apparatus, an annealing apparatus, a sputtering apparatus, a deposition apparatus, or the like. Furthermore, the substrate processing apparatus 1 may be a planarization apparatus that uses a flat plate to planarize a composition on a substrate.

The substrate processing apparatus 1 includes an illumination optical system 2 that irradiates light, a projection optical system 3, a reticle stage 6 that holds a reticle 4, a substrate stage 7 that can be driven (moved) in the X and Y directions while holding a substrate 5, and a main control unit (information processing unit) 8. The substrate stage 7 may be driven (moved) in the Z direction without being limited to the X and Y directions. Further, the substrate stage 7 may include a six-axis driving system that can drive in the X-axis, Y-axis, and Z-axis directions, and around the X-axis, Y-axis, and Z-axis. The substrate stage 7 also includes a stage control unit 9.

A position of the substrate stage 7 in the Y-axis direction is measured by a bar mirror 10 that extends along the X-axis direction on the substrate stage 7, and a laser interferometer 11. Further, the position of the substrate stage 7 in the X-axis direction is measured by a bar mirror (not illustrated) that extends along the Y-axis direction on the substrate stage 7, and a laser interferometer (not illustrated). A plurality of laser interferometers 11 for measuring the position of the substrate stage 7 in the Y-axis direction and a plurality of laser interferometers for measuring the position of the substrate stage 7 in the X-axis direction may be provided. This configuration makes it possible to measure the position of the substrate stage 7 in the X-axis direction and the Y-axis direction as well as a shift amount in the rotation direction around the X-axis, a shift amount in the rotation direction around the Y-axis, and a shift amount in the rotation direction around the Z-axis. According to the present embodiment, an example in which the position of the substrate stage 7 is measured by an interferometer system is described, but the position of the substrate stage 7 may be measured by another measure, such as an encoder.

A position of the reticle stage 6 in the Y-axis direction is measured by a bar mirror 12 that extends along the X-axis direction on the reticle stage 6, and a laser interferometer 13. Further, the position of the reticle stage 6 in the X-axis direction is measured by a bar mirror (not illustrated) that extends along the Y-axis direction on the reticle stage 6, and a laser interferometer (not illustrated).

The reticle 4 is, for example, an original plate in which a pattern to be transferred (e.g., a circuit pattern) is formed on a surface of quartz glass by chromium. Further, the substrate 5 is, for example, single crystal silicon, and in a case where the substrate processing apparatus 1 is an exposure apparatus, a photosensitive material (resist) is applied onto a surface of the substrate 5 that is to be conveyed to the substrate processing apparatus 1. Here, the illumination optical system 2 is a pattern forming unit that forms a pattern on the substrate 5. According to the present embodiment, an example of a lithography apparatus that forms a pattern using light is described, and the pattern forming unit is the illumination optical system 2, but the lithography apparatus may be one that cures a thermosetting material onto which a pattern is transferred by heat. The pattern forming unit in that case is, for example, a heating unit that heats the thermosetting material. A part of the substrate processing apparatus 1 that processes the substrate is a substrate processing unit, and for example, if the substrate processing apparatus 1 is a projection exposure apparatus, an illumination optical system and a projection optical system are included in the substrate processing unit. In a case where the substrate processing apparatus 1 is an imprint apparatus or a planarization apparatus, an illumination optical system and a heating unit for curing an imprint material or a composition are included in the substrate processing unit.

The main control unit 8 controls each unit within the substrate processing apparatus 1, and the stage control unit 9 controls driving (movement) of the substrate stage 7. Further, the main control unit 8 is an information processing apparatus that adjusts (determines) a driving profile of the substrate stage 7 by using a method described below. The main control unit 8 transmits the adjusted (determined) driving profile to the stage control unit 9. The stage control unit 9 controls driving (movement) of the substrate stage 7 based on the driving profile transmitted from the main control unit 8 and the position of the substrate stage 7 acquired by the above-described bar mirror and laser interferometer, to move the substrate 5 to a desired position.

The main control unit 8 and the stage control unit 9 each include a processing unit, a bus, a read-only memory (ROM), a random access memory (RAM), and a storage device, and each component functions according to a program. The processing unit is a processing apparatus that performs a calculation for control according to a program and controls each component connected to the bus. The processing unit can be configured with a central processing unit (CPU), a programmable logic device (PLD) such as a field programmable gate array (FPGA), an application specific integrated circuit (ASIC), a computer with an embedded program, or a combination of all or part of these. The ROM is a memory dedicated to reading data, and stores a program and data. The RAM is a memory for reading and writing data, and is used to store a program and data. The RAM is used to temporarily store data such as a result of a calculation by the CPU or the like. The storage device is also used to store a program and data. The storage device is also used as a temporary storage area for a program and data of an operating system (OS) of the main control unit 8 and the stage control unit 9. The storage device is slower in data input and output compared with the RAM, but it is capable of storing a large amount of data. It is desirable that the storage device be a nonvolatile storage device capable of storing data as persistent data so that the stored data can be referenced over a long period of time. The storage device is mainly configured with a magnetic storage device (hard disk drive (HDD)), but it may also be a device that reads and writes data by loading an external medium, such as a compact disk (CD), a digital versatile disk (DVD), or a memory card.

In the substrate processing apparatus 1, exposure light from a light source (not illustrated) illuminates the reticle 4 held by the reticle stage 6 via the illumination optical system 2. The light transmitted through the reticle 4 is projected onto the substrate 5 via the projection optical system 3. At this time, the light from the pattern formed on the reticle 4 forms an image on the surface of the substrate 5, and the substrate 5 (photosensitive material) is exposed by the pattern image. The substrate processing apparatus 1 exposes a shot area on the substrate 5 in such a manner, and performs exposure in the same manner on each of a plurality of shot areas.

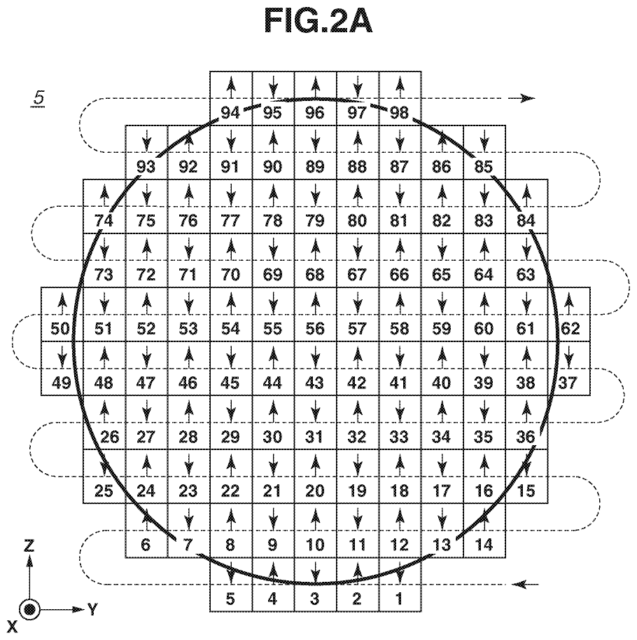

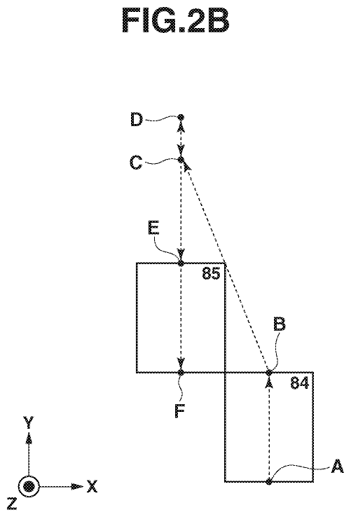

FIGS. 2A and 2B are schematic diagrams illustrating the substrate 5 being scanned for exposure. FIG. 2A illustrates a shot layout of a plurality of shot areas on the substrate 5, and according to the present embodiment, 98 shot areas are provided on the substrate 5. The number in each shot area indicates the order in which each shot area is scanned for exposure, and the plurality of shot areas on the substrate 5 is scanned for exposure in order as indicated by a dotted line. An arrow illustrated in each shot area indicates a direction in which each shot area is scanned for exposure.

FIG. 2B illustrates an example of a locus of a position of the projection optical system 3 relative to the substrate stage 7 in exposing the shot area. According to the present embodiment, the Y-axis direction is a scanning direction. In practice, scanning exposure is performed by changing a relative position between the projection optical system 3 and the substrate stage 7 as the substrate stage 7 moves relative to the fixed projection optical system 3, but for convenience of description, the locus of the position of the projection optical system 3 relative to the substrate stage 7 is described. FIG. 2B illustrates 84th and 85th shot areas to be exposed among the shot areas illustrated in FIG. 2A. First, exposure on the 84th shot area is started from a position A, and the exposure on the 84th shot area ends when the projection optical system 3 reaches a position B. Then, in order to expose the 85th shot area, the substrate stage 7 is moved in a +X direction while moving in a −Y direction, and the projection optical system 3 reaches a position C. Subsequently, the substrate stage 7 is moved in the −Y direction, thus the projection optical system 3 reaches a position D, and the velocity of the substrate stage 7 is zero at the position D. Next, the substrate stage 7 is moved in a +Y direction, thus the projection optical system 3 reaches a position E, which is an exposure start position for the 85th shot area, and exposure on the 85th shot area is started from the position E. As the substrate stage 7 is moved in the +Y direction, the projection optical system 3 reaches a position F, which is an exposure end position for the 85th shot area.

The 85th shot area is different from the 84th shot area in the position of the shot area in the Y-axis direction (scanning direction) on the substrate, and thus the movement of the substrate stage 7 between the shot areas having such a positional relationship is sometimes referred to as starting a new line. Particularly, in starting a new line, a moving distance of the substrate stage 7 in the Y-axis direction is longer than a moving distance of the substrate stage 7 in the X-axis direction as illustrated in FIG. 2B.

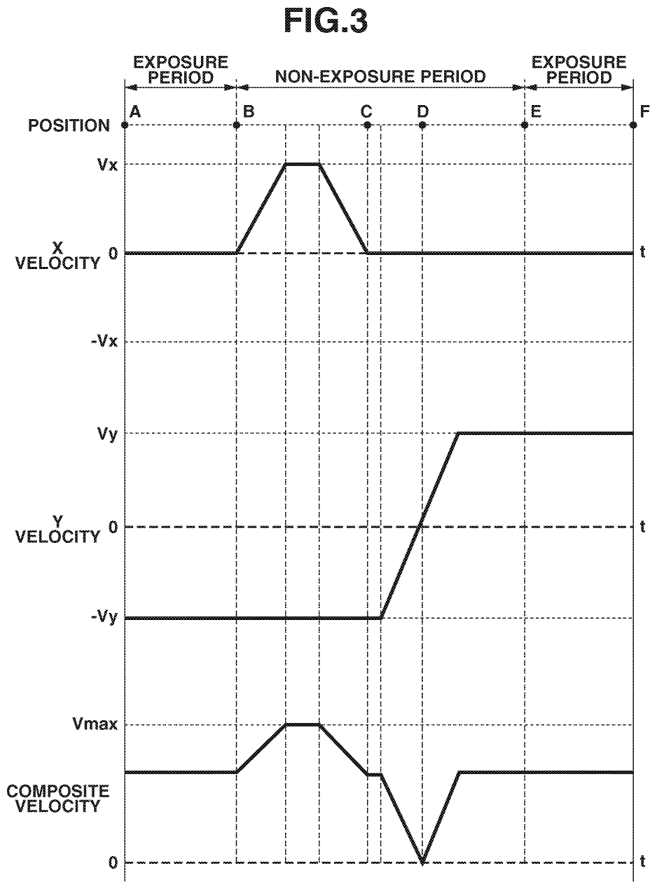

FIG. 3 is a diagram illustrating a driving profile of the substrate stage 7 at the time of exposing the 84th shot area and the 85th shot area in a conventional example. An upper graph in FIG. 3 illustrates a driving velocity of the substrate stage 7 in the X-axis direction (hereinbelow sometimes referred to as the X velocity), and a middle graph illustrates the driving velocity of the substrate stage 7 in the Y-axis direction (hereinbelow sometimes referred to as the Y velocity). A lower graph illustrates the driving velocity of the substrate stage 7 obtained by combining driving velocity of the substrate stage 7 in the X-axis direction and the driving velocity of the substrate stage 7 in the Y-axis direction (hereinbelow sometimes referred to as the composite velocity). According to the present embodiment, the driving velocity of the substrate stage 7 is sometimes referred to as the moving velocity of the substrate stage 7.

Using the example in FIG. 3, scanning exposure is being performed between the positions A and B, and there is no movement in the X-axis direction, so that the X velocity is zero, and the Y velocity is a constant velocity of −Vy. When the projection optical system 3 reaches the position B, the X velocity starts to increase and continues to increase until the X velocity reaches Vx. Meanwhile, the Y velocity remains at −Vy. Then, the X velocity decreases from Vx to zero by the position C, and the movement in the X-axis direction is completed. Further, the Y velocity approaches zero between the positions C and D, and the Y velocity reaches zero at the position D. Next, between the positions D and E, the movement in the X-axis direction is completed, so that the X velocity is zero, and the Y velocity increases to Vy. Then, scanning exposure is being performed between the positions E and F, and there is no movement in the X-axis direction, so that the X velocity is zero, and the Y velocity is the constant velocity of Vy.

Here, a maximum value (hereinbelow sometimes referred to as a limit velocity) of the composite velocity of the substrate stage 7 is determined by the hardware configuration, and the limit velocity is the maximum velocity within a range of allowable velocities at which the substrate stage 7 can perform normal operations a plurality of times without any problems. In other words, the limit velocity of the composite velocity is a limit value of the composite velocity. For example, the substrate stage 7 may include a coarse movement stage and a fine movement stage that moves together with the coarse movement stage in a non-contact state with the coarse movement stage by an electromagnetic actuator or the like. In this case, the limit velocity of the composite velocity is defined, for example, as a limit velocity at which the fine movement stage, which does not include a brake mechanism, will not collide with the coarse movement stage even if the coarse movement stage stops from the limit velocity. In other words, the limit velocity of the composite velocity is defined as a limit velocity at which an electromagnetic actuator can suppress a collision between the coarse movement stage and the fine movement stage. Alternatively, the limit velocity of the composite velocity is defined as a limit velocity at which a component (e.g., a fine movement top plate) or the like included in the substrate stage 7 does not damage even if the component hits a shock absorber (impact absorbing device) or the like, as long as the composite velocity is the limit velocity or lower. In addition, the limit velocity of the composite velocity may be defined based on a specification or the like of a driving mechanism (e.g., a linear motor) included in the substrate stage 7. Further, the limit velocity of the composite velocity may also be a variable. For example, the limit velocity of the composite velocity may be determined depending on a driving direction, a driving start position, or the like of the substrate stage 7.

The main control unit 8 determines the X velocity and the Y velocity such that the composite velocity becomes a limit velocity Vmax or less and determines a driving profile of the substrate stage 7. In other words, the main control unit 8 determines the X velocity (Vx) and the Y velocity (Vy) to satisfy Formula (1), thereby determining the driving profile of the substrate stage 7.

$$\begin{matrix}[ Formula 1 ] & \\ V max \geq \sqrt{{Vx}^{2} + {Vy}^{2}} & Formula ( 1 )\end{matrix}$$

In the case of the example in FIG. 3, timing at which an absolute value of the X velocity reaches a maximum (Vx) and timing at which an absolute value of the Y velocity reaches a maximum (−Vy) overlap, so that the X velocity and the Y velocity are mutually limited. Further, if the Y velocity is limited (the Y velocity becomes slow), a driving time of the substrate stage 7 becomes long, and throughput (productivity) is reduced.

Thus, the substrate stage 7 according to the present embodiment determines (adjusts) timing for moving in the X-axis direction during a non-exposure period. Accordingly, the timing at which the absolute value of the X velocity reaches the maximum is made different from the timing at which the absolute value of the Y velocity reaches the maximum, thereby reducing mutual limitation of the X velocity and the Y velocity. Accordingly, it is possible to improve the Y velocity and shorten the driving time of the substrate stage 7. According to the present embodiment, a parameter in the X-axis direction is determined based on the Y velocity in the Y-axis direction, but another parameter may be determined based on a velocity in a direction in which the moving distance of the substrate stage 7 is long, in other words, in a direction that is more likely to be rate-determining. According to the present embodiment, time is sometimes expressed as timing.

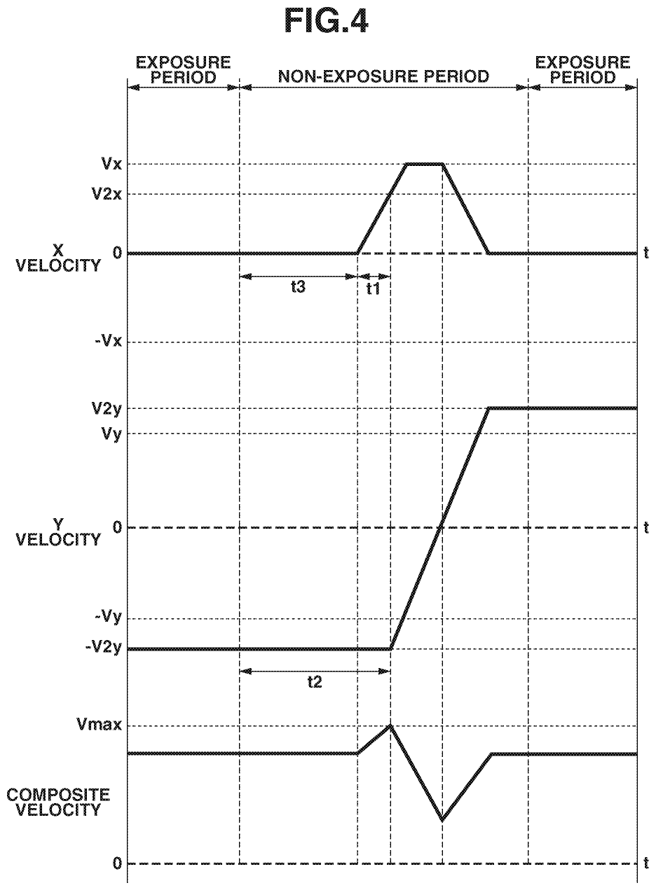

FIG. 4 is a diagram illustrating the driving profile of the substrate stage 7 at the time of exposing the 84th shot area and the 85th shot area according to the present embodiment. The upper graph in FIG. 4 illustrates the X velocity of the substrate stage 7, the middle graph illustrates the Y velocity of the substrate stage 7, and the lower graph illustrates the composite velocity of the substrate stage 7.

According to the present embodiment, the timing at which the substrate stage 7 starts moving in the X-axis direction is shifted by time t3. Specifically, the timing at which the substrate stage 7 starts moving in the X-axis direction is determined (adjusted) based on a first parameter (Y velocity). Accordingly, the timing at which the absolute value of the X velocity reaches the maximum and the timing at which the absolute value of the Y velocity reaches the maximum do not overlap, so that the Y velocity can be improved.

First, the main control unit 8 determines ±V2y, which is the Y velocity that satisfies desired throughput and production condition (e.g., a scanning velocity in exposure), as the Y velocity (first parameter). This determination is made based on, for example, a shot layout, an order in which a plurality of shot areas is exposed, a specification of an article to be manufactured, and the like. The Y velocity (first parameter) may be set by a user inputting from an input apparatus (not illustrated). The absolute value of ±V2y can be set to a value greater than the absolute value of ±Vy in the conventional example, and is, for example, a value that satisfies Formula (2).

$$\vert \pm Vy \vert < \vert \pm V 2 y \vert \qquad Formula ( 2 )$$

Next, the main control unit 8 calculates the X velocity ±V2x that satisfies Formulas (3) and (4) based on the determined Y velocity ±V2y.

$$\vert \pm Vx \vert < \vert \pm V 2 x \vert \qquad Formula ( 3 )$$

$$\begin{matrix}[ Formula 4 ] & \\ V max \geq \sqrt{{V 2 x}^{2} + {V 2 y}^{2}} & Formula ( 4 )\end{matrix}$$

Next, the main control unit 8 calculates time t1 required for the substrate stage 7 to reach the calculated X velocity ±V2x after the substrate stage 7 starts moving in the X-axis direction. Then, the main control unit 8 calculates time t3 (second parameter) from time t2 and time t1 by using Formula (5). The time t2 is a time from the end of exposure of the previous shot until the Y velocity changes from −V2y (maximum velocity) (the time during which the absolute value of the Y velocity remains at the maximum after the end of exposure of the previous shot).

$$t 3 = t 2 - t 1 \qquad Formula ( 5 )$$

The main control unit 8 determines a driving profile in which the timing at which the substrate stage 7 starts moving in the X-axis direction is shifted by the calculated time t3. Accordingly, the timing at which the absolute value of the X velocity reaches the maximum (|±V x|) and the timing at which the absolute value of the Y velocity reaches the maximum (|±V2 y|) do not overlap. Thus, the maximum absolute value (|±V2 y|) of the Y velocity according to the present embodiment can be made greater than the maximum absolute value (|±V y|) of the Y velocity in the conventional example, and throughput can be improved.

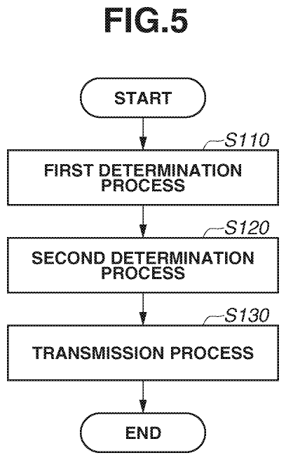

FIG. 5 is a diagram illustrating a flowchart for determining a driving profile according to the present embodiment. The main control unit 8 determines the second parameter that is a parameter related to the movement of the substrate stage 7 in a second direction (X-axis direction) based on the first parameter serving as a parameter related to the movement of the substrate stage 7 in a first direction (Y-axis direction) (Step S110, a first determination process). Here, the moving distance of the substrate stage 7 in the first direction is longer than the moving distance thereof in the second direction. The moving distance in each direction can be calculated based on the shot layout, the order in which a plurality of shot areas is exposed, and the like. The first determination process according to the present embodiment is a process for determining the time t3, which is the second parameter, at which the movement in the X-axis direction is started, based on the Y velocity, which is the first parameter. Next, the main control unit 8 determines a driving profile for controlling the movement of the substrate stage 7 based on the first parameter and the second parameter that has been determined in the first determination process (Step S120, a second determination process). In other words, the driving profile is determined based on the first parameter and the second parameter that has been determined in the first determination process. Then, the main control unit 8 transmits the driving profile determined in the second determination process to the stage control unit 9 (Step S130, a transmission process). Determining a driving profile includes generating a driving profile as well as adjusting a driving profile. Steps S110 to S130 are an information processing method that is executed by the main control unit (information processing apparatus) 8 in accordance with a program stored therein.

According to the present embodiment, the driving profile of the substrate stage 7 at the time of exposing the 84th shot area and the 85th shot area has been described as an example, but the present embodiment is also applicable to other shot areas.

When the timing for starting the movement in the X-axis direction is delayed, it is desirable to consider a relationship between time when the movement in the X-axis direction is completed and exposure start time of the next shot area. First, the movement in the X-axis direction needs to be completed by the exposure start time of the next shot area. Further, in a case where the time at which the movement in the X-axis direction is completed is too close to the exposure start time of the next shot area, exposure accuracy of the next shot area may be deteriorated due to an effect of vibration or the like caused by the movement. It is desirable to determine the time t3 for shifting the timing for starting the movement in the X-axis direction in consideration of these factors as well.

According to the present embodiment, an example has been described in which the main control unit 8 determines the driving profile of the substrate stage 7 as an information processing apparatus, but the driving profile may be determined by the stage control unit 9, or by an information processing apparatus external to the substrate processing apparatus 1. In a case where the stage control unit 9 determines the driving profile, the transmission process does not need to be performed. In a case where the information processing apparatus external to the substrate processing apparatus 1 determines the driving profile, the driving profile determined in the second determination process may be transmitted from the information processing apparatus to the stage control unit 9 in the transmission process, or may be transmitted to the main control unit 8 that controls the substrate processing apparatus 1.

According to the present embodiment, an example has been described in which the second parameter is determined based on the first parameter, and the driving profile is determined. The driving profile may include a first driving profile to be used to control the movement of the substrate stage 7 in the Y-axis direction (first direction) and a second driving profile to be used to control the movement of the substrate stage 7 in the X-axis direction (second direction). In other words, the driving profile may be managed and determined for each direction. In this case, the driving profile in the Y-axis direction (first driving profile) is determined based on the first parameter, and the driving profile in the X-axis direction (second driving profile) is determined based on the second parameter.

According to the present embodiment, an example in which a driving profile is determined has been mainly described, but an embodiment that adjusts a driving profile stored in the storage device may also be adopted. For example, in a case where the storage device (storage unit) stores the first driving profile and the second driving profile, the second driving profile stored in the storage device may also be adjusted based on the second parameter.

In addition to adjusting the second driving profile, the first driving profile may also be adjusted based on the first parameter and the second parameter. This adjustment may be performed a plurality of times. Further, according to the present embodiment, the driving of the substrate stage 7 in the X-axis direction is determined based on the driving of the substrate stage 7 in the Y-axis direction. However, in a case where the moving distance of the substrate stage 7 in the X-axis direction is longer than the moving distance of the substrate stage 7 in the Y-axis direction, the driving of the substrate stage 7 in the Y-axis direction may also be determined (adjusted) based on the driving of the substrate stage 7 in the X-axis direction.

In other words, the adjustment according to the present embodiment is to adjust at least one of the first driving profile and the second driving profile based on the composite velocity obtained by combining the moving velocity of the substrate stage 7 in the first direction and the moving velocity of the substrate stage 7 in the second direction. Specifically, the timing at which the substrate stage 7 starts moving is adjusted in at least one of the first driving profile and the second driving profile. The moving velocity of the substrate stage 7 in the first direction can be acquired from the first driving profile, and the moving velocity of the substrate stage 7 in the second direction can be acquired from the second driving profile.

According to the present embodiment, an example has been described in which the maximum Y velocity during an exposure period is the same as the maximum Y velocity during the non-exposure period are the same, but the maximum Y velocity during the exposure period may be different from the maximum Y velocity during the non-exposure period. For example, during the exposure period, the Y velocity (scanning velocity) may be set based on a specification of an article (a chip or the like) to be manufactured, and during the non-exposure period, the Y velocity faster than the scanning velocity may be set to improve throughput.

According to the present embodiment, the time (second parameter) at which the substrate stage 7 starts moving in the X-axis direction (second direction), which is a direction in which the moving distance of the substrate stage 7 is shorter than that in the Y-axis direction, is determined based on the moving velocity (the Y velocity, the first parameter) of the substrate stage 7 in the Y-axis direction (first direction). Accordingly, the timing at which the absolute value of the X velocity reaches the maximum (|±V x|) and the timing at which the absolute value of the Y velocity reaches the maximum (|±V2 y|) do not overlap, and the X velocity and the Y velocity are not mutually limited. Thus, the driving time of the substrate stage 7 becomes shorter than that in the conventional example, and throughput (productivity) can be improved.

### Second Embodiment

The present embodiment is different from the first embodiment in a method for determining (adjusting) a driving profile such that the timing at which the absolute value of the X velocity reaches the maximum and the timing at which the absolute value of the Y velocity reaches the maximum do not overlap. According to the present embodiment, acceleration of the movement of the substrate stage 7 in the X-axis direction during the non-exposure period is changed so that the timing at which the absolute value of the X velocity reaches the maximum and the timing at which the absolute value of the Y velocity reaches the maximum are different from each other.

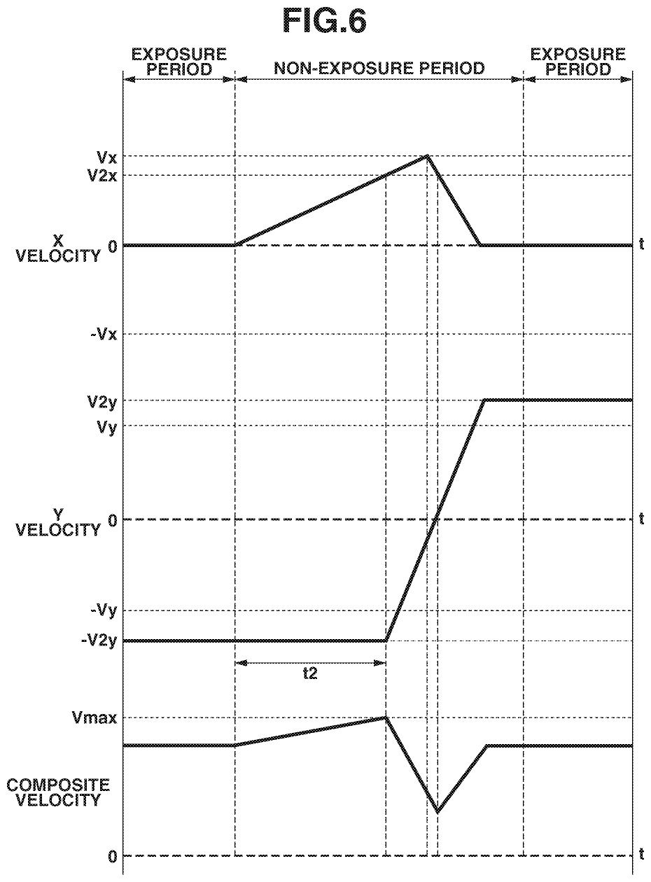

FIG. 6 is a diagram illustrating a driving profile of the substrate stage 7 at the time of exposing the 84th shot area and the 85th shot area according to the present embodiment.

The main control unit 8 calculates the X velocity ±V2x based on the determined Y velocity (first parameter), as in the first embodiment. According to the present embodiment, the time t2 that elapses from the end of exposure of the previous shot until the Y velocity changes from −V2y (the time during which the absolute value of the Y velocity remains at the maximum after the end of exposure of the previous shot) is made equal to the time at which the absolute value of the X velocity reaches |±V2 x|. Specifically, the acceleration (second parameter) at the time when the absolute value of the X velocity changes to |±V2 x| is made small so that the X velocity gradually increases. Accordingly, the timing at which the absolute value of the X velocity reaches the maximum |±V x| and the timing at which the absolute value of the Y velocity reaches the maximum (|±V2 y|) do not overlap. Thus, the maximum absolute value (|±V2 y|) of the Y velocity according to the present embodiment can be made greater than the maximum absolute value (|±V y|) of the Y velocity in the conventional example, and throughput can be improved.

According to the present embodiment, as in the first embodiment, in a case where the moving distance of the substrate stage 7 in the X-axis direction is longer than the moving distance of the substrate stage 7 in the Y-axis direction, the driving of the substrate stage 7 in the Y-axis direction may be determined (adjusted) based on the driving of the substrate stage 7 in the X-axis direction.

In other words, in the adjustment according to the present embodiment, as in the first embodiment, at least one of the first driving profile and the second driving profile is adjusted based on the composite velocity obtained by combining the moving velocity of the substrate stage 7 in the first direction and the moving velocity of the substrate stage 7 in the second direction.

Specifically, the acceleration of the substrate stage 7 is adjusted in at least one of the first driving profile and the second driving profile.

According to the present embodiment, the driving profile of the substrate stage 7 at the time of exposing the 84th shot area and the 85th shot area has been described as an example, but the present embodiment is also applicable to other shot areas. Further, the determination (adjustment) of the acceleration in the X-axis direction according to the present embodiment and the determination (adjustment) of the timing for starting the movement in the X-axis direction according to the first embodiment may also be performed together.

### Third Embodiment

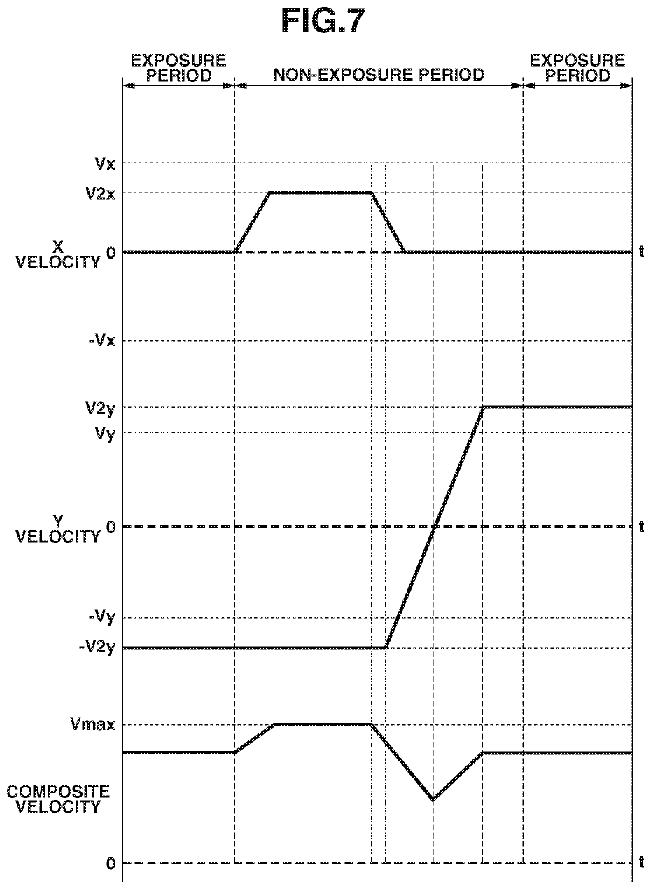

The present embodiment is different from the first embodiment and the second embodiment in a method for determining (adjusting) a driving profile. FIG. 7 is a diagram illustrating a driving profile of the substrate stage 7 at the time of exposing the 84th shot area and the 85th shot area according to the present embodiment.

The main control unit 8 calculates the X velocity ±V2x (second parameter) based on the determined Y velocity (first parameter), as in the first embodiment. According to the present embodiment, an absolute value of the maximum X velocity during the non-exposure period is |±V2 x|. Accordingly, it is possible to set the Y velocity to the maximum absolute value (|±2V y|) of the Y velocity that is greater than the maximum absolute value (|±V y|) of the Y velocity in the conventional example, and throughput can be improved.

In a case where the absolute value of the maximum X velocity is set to |±V2 x| (in a case where the absolute value of the maximum X velocity is reduced), it is desirable to consider the relationship between the time at which the movement in the X-axis direction is completed and the exposure start time of the next shot area. First, the movement in the X-axis direction needs to be completed by the exposure start time of the next shot area. Further, in a case where the time at which the movement in the X-axis direction is completed is too close to the exposure start time of the next shot area, exposure accuracy of the next shot area may be deteriorated due to the effect of vibration or the like caused by the movement. It is desirable to determine |±V2 x|, which is the absolute value of the maximum X velocity, in consideration of these factors as well.

Here, according to the present embodiment, the maximum X velocity is set to ±V2x, but if further movement in the X-axis direction is required at the timing at which the Y velocity is no longer the maximum absolute value (|±V2 y|), the X velocity may be further increased from ±V2x to an extent that does not affect the Y velocity.

According to the present embodiment, as in the first embodiment, in a case where the moving distance of the substrate stage 7 in the X-axis direction is longer than the moving distance of the substrate stage 7 in the Y-axis direction, the driving of the substrate stage 7 in the Y-axis direction may be determined (adjusted) based on the driving of the substrate stage 7 in the X-axis direction.

In other words, in the adjustment according to the present embodiment, as in the first embodiment, at least one of the first driving profile and the second driving profile is adjusted based on the composite velocity obtained by combining the moving velocity of the substrate stage 7 in the first direction and the moving velocity of the substrate stage 7 in the second direction.

Specifically, the maximum velocity of the substrate stage 7 (in a predetermined direction) is adjusted in at least one of the first driving profile and the second driving profile.

The present embodiment may be implemented in combination with either or both of the first embodiment and the second embodiment. In other words, in at least one of the first driving profile and the second driving profile, the driving profile is adjusted in at least one or more of the timing at which the substrate stage 7 is moved, the acceleration of the substrate stage 7, and the maximum velocity of the substrate stage.

According to the present embodiment, the driving profile of the substrate stage 7 at the time of exposing the 84th shot area and the 85th shot area has been described as an example, but the present embodiment is also applicable to other shot areas.

### Fourth Embodiment

The present embodiment is different from the above-described embodiments in a method for determining (adjusting) a driving profile. For example, in order to detect each of alignment marks formed in a plurality of sample shot areas, the substrate stage 7 may move each of two shot areas, which are located at discrete positions, successively to a target position (e.g., an alignment mark detection position). As a specific example, for example, it is assumed that the 87th shot area and the 8th shot area are the sample shot areas among the plurality of shot areas on the substrate 5 illustrated in FIG. 2A. In this case, first, the substrate stage 7 is moved such that the 87th shot area moves to the target position, and the alignment mark in the 87th shot area is detected. Next, the substrate stage 7 is moved such that the 8th shot area moves to the target position, and the alignment mark in the 8th shot area is detected.

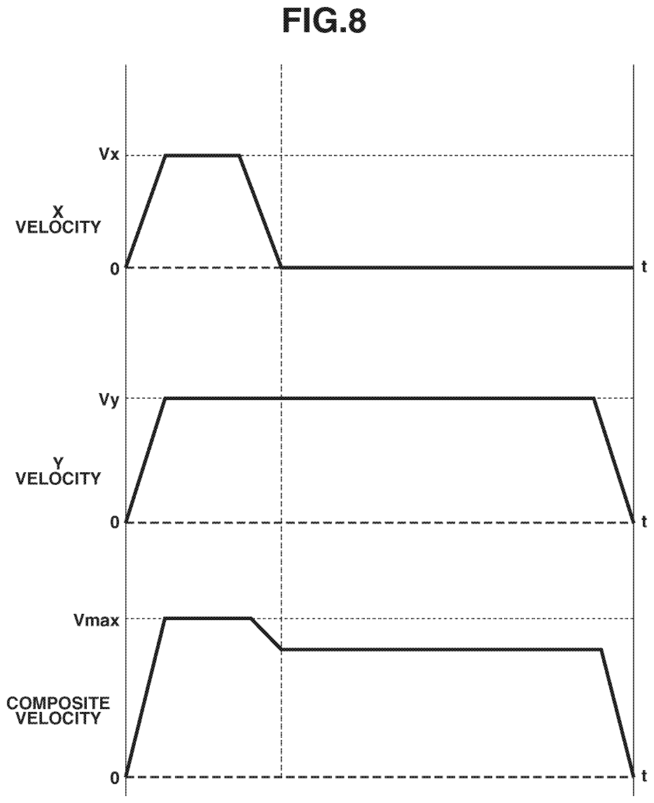

FIG. 8 is a diagram illustrating a driving profile of the substrate stage 7 at the time of moving the 87th shot area to the target position and then moving the 8th shot area in the conventional example.

The upper graph in FIG. 8 illustrates the X velocity of the substrate stage 7, the middle graph illustrates the Y velocity of the substrate stage 7, and the lower graph illustrates the composite velocity of the substrate stage 7.

As illustrated in FIG. 8, conventionally, the movement in the X-axis direction and the movement in the Y-axis direction were started simultaneously, so that the X velocity and the Y velocity were mutually limited. The main control unit 8 calculated the X velocity Vx and the Y velocity Vy that satisfied Formula (1), and the stage control unit 9 controlled the movement of the substrate stage 7 at a constant velocity Vx in the movement in the X-axis direction and at a constant velocity Vy in the movement in the Y-axis direction. Accordingly, the substrate stage 7 is moved at the X velocity and the Y velocity that are mutually limited, and thus the driving time of the substrate stage 7 becomes long.

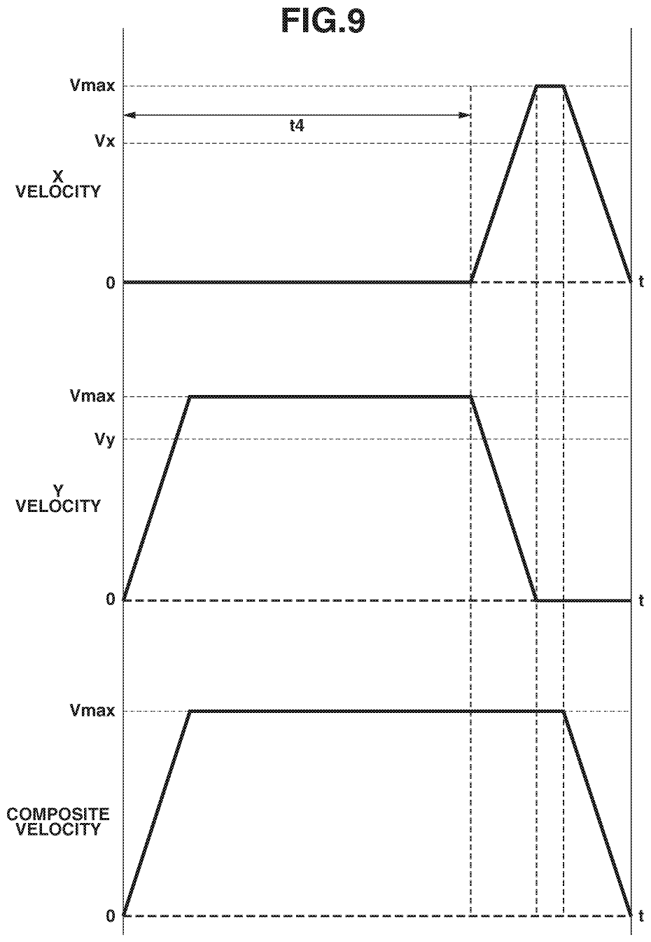

FIG. 9 is a diagram illustrating a driving profile of the substrate stage 7 at the time of moving the 87th shot area to the target position and then moving the 8th shot area according to the present embodiment. The upper graph in FIG. 9 illustrates the X velocity of the substrate stage 7, the middle graph illustrates the Y velocity of the substrate stage 7, and the lower graph illustrates the composite velocity of the substrate stage 7.

In a case where the substrate stage 7 is moved from a state in which the 87th shot area is located at the target position to a state in which the 8th shot area comes to the target position, the main control unit 8 determines the driving profile so as to move the substrate stage 7 first only in the Y-axis direction with the Y velocity set to the limit velocity Vmax.

Then, the main control unit 8 determines the driving profile such that the X velocity increases from the timing (first parameter) at which the Y velocity changes from the limit velocity Vmax (maximum velocity), and the X velocity reaches the limit velocity Vmax at the timing when the Y velocity becomes zero. In other words, the main control unit 8 determines the driving profile so as to shift the timing (second parameter) at which the substrate stage 7 starts moving in the X-axis direction to time t4 that is timing at which the Y velocity changes from the limit velocity Vmax. That is, the main control unit 8 determines (adjusts) the timing (second parameter) at which the substrate stage 7 starts moving in the X-axis direction based on the first parameter.

By determining the driving profile in this way, the X velocity and the Y velocity are not mutually limited, and each can be set to the limit velocity Vmax. Accordingly, the driving time of the substrate stage 7 can be shortened.

According to the present embodiment, the driving profile of the substrate stage 7 at the time of moving the 87th shot area to the target position and then moving the 8th shot area has been described as an example, but the present embodiment is also applicable to other shot areas. Further, according to the present embodiment, an example has been described in which the substrate stage 7 is first driven in the Y-axis direction and then driven in the X-axis direction, and an example has also been described in which a parameter in the X-axis direction is determined based on a parameter in the Y-axis direction. However, the other parameter may be determined based on a velocity in a direction in which the moving distance of the substrate stage 7 is long, in other words, in a direction that is more likely to be rate-determining, and it is not particularly limited to the example of the present embodiment.

As in the first embodiment, the present embodiment may also be realized by adjusting the driving profile stored in the storage unit. In other words, this adjustment is to adjust at least one of the first driving profile and the second driving profile based on the composite velocity obtained by combining the moving velocity of the substrate stage 7 in the first direction and the moving velocity of the substrate stage 7 in the second direction.

### Fifth Embodiment

The present embodiment is characterized in that an article is manufactured by moving the substrate stage 7 using the above-described driving profile.

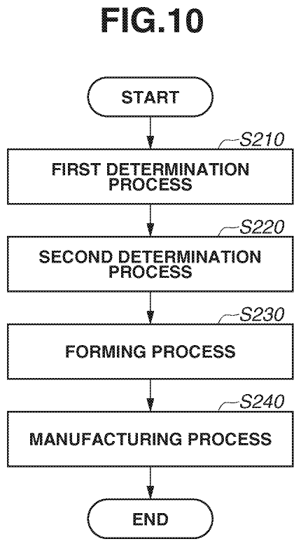

FIG. 10 is a diagram illustrating a flowchart for a manufacturing method for an article according to the present embodiment. The main control unit (information processing apparatus) 8 determines the second parameter that is a parameter related to the movement of the substrate stage 7 in the second direction based on the first parameter that is a parameter related to the movement of the substrate stage 7 in the first direction (Step S210, the first determination process). Here, the moving distance of the substrate stage 7 in the first direction is longer than the moving distance thereof in the second direction. Next, the main control unit 8 determines a driving profile for controlling the movement of the substrate stage 7 based on the first parameter and the second parameter that has been determined in the first determination process (Step S220, the second determination process). Then, a forming process (Step S230) is performed to form a pattern on the substrate while controlling the movement of the substrate stage 7 that holds the substrate based on the driving profile determined in the second determination process. Next, a manufacturing process (Step S240) to manufacture an article from the substrate on which the pattern has been formed in the forming process is performed.

An article to be manufactured by this manufacturing method is, for example, a semiconductor integrated circuit (IC) element, a liquid crystal display element, a color filter, a micro-electromechanical system (MEMS), or the like.

In the forming process, for example, a substrate (a silicon wafer, a glass plate, or the like) coated with a photosensitive material is exposed by an exposure apparatus (lithography apparatus) to form a pattern on the substrate.

The manufacturing process includes, for example, developing the substrate (photosensitive material) on which the pattern is formed, etching the developed substrate, resist stripping, dicing, bonding, and packaging. According to the present manufacturing method, it is possible to manufacture an article with higher throughput than that in the conventional example.

The present disclosure is not limited to the above-described embodiments, and various modifications and changes can be made without departing from the spirit and the scope of the present disclosure. Therefore, the following claims are attached in order to publicize the scope of the present disclosure.

According to the present disclosure, it is possible to provide a stage apparatus that is capable of shortening a driving time.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

1. A stage apparatus comprising:
a stage configured to move while holding a substrate; and
a control unit configured to control movement of the stage based on a driving profile,
wherein the driving profile is determined based on a first parameter that is a parameter related to movement of the stage in a first direction and a second parameter that is a parameter related to movement of the stage in a second direction determined based on the first parameter, and
wherein a moving distance of the stage in the first direction is longer than a moving distance in the second direction.

2. The stage apparatus according to claim 1, wherein the second parameter is determined based on the first parameter and a limit velocity of a composite velocity of a moving velocity of the stage in the first direction and a moving velocity of the stage in the second direction.

3. The stage apparatus according to claim 1, wherein the first parameter is a velocity at which the stage moves in the first direction, and the second parameter is time at which the stage starts moving in the second direction, acceleration at the time of the stage moving in the second direction, or a maximum velocity at the time of the stage moving in the second direction.

4. The stage apparatus according to claim 1, wherein the first parameter is time at which a moving velocity of the stage in the first direction changes from a maximum velocity, and the second parameter is time at which the stage starts moving in the second direction.

5. The stage apparatus according to claim 1, wherein a velocity at which the stage moves in the first direction and a velocity at which the stage moves in the second direction respectively reach maximum velocities at mutually different times.

6. The stage apparatus according to claim 1, wherein the first direction is a scanning direction in which scanning exposure is performed on the substrate, and the second direction is a direction perpendicular to the first direction.

7. The stage apparatus according to claim 1,
wherein the driving profile includes a first driving profile that is used to control movement of the stage in the first direction and a second driving profile that is used to control movement of the stage in the second direction, and
wherein the first driving profile is determined based on the first parameter, and the second driving profile is determined based on the second parameter.

8. The stage apparatus according to claim 1, further comprising a storage unit configured to store a second driving profile that is used to control movement of the stage in the second direction,
wherein the second driving profile stored in the storage unit is adjusted based on the second parameter.

9. The stage apparatus according to claim 8,
wherein the storage unit stores a first driving profile that is used to control movement of the stage in the first direction, and
wherein the first driving profile is adjusted based on the first parameter and the second parameter.

10. The stage apparatus according to claim 1, wherein the driving profile is used to control movement of the stage during a non-exposure period.

11. The stage apparatus according to claim 1, wherein the driving profile is used when the stage moves between shot areas of which positions are different in the scanning direction of the stage.

12. A stage apparatus comprising:
a stage configured to be driven while holding a substrate; and
a control unit configured to control driving of the stage based on a driving profile,
wherein the driving profile includes a first driving profile that is used for driving of the stage in a first direction and a second driving profile that is used for driving of the stage in a second direction, and
wherein the control unit controls driving of the stage using the driving profile in which at least one of the first driving profile and the second driving profile is adjusted based on a composite velocity of a moving velocity of the stage in the first direction and a moving velocity of the stage in the second direction.

13. The stage apparatus according to claim 12, wherein, in at least one of the first driving profile and the second driving profile, the driving profile is adjusted in at least one or more of time at which the stage starts moving, acceleration of the stage, and a maximum velocity of the stage.

14. A substrate processing apparatus comprising:
a stage configured to move while holding a substrate;
a control unit configured to control movement of the stage based on a driving profile; and
a substrate processing unit configured to perform processing on the substrate held by the stage,
wherein the driving profile is determined based on a first parameter that is a parameter related to movement of the stage in a first direction and a second parameter that is a parameter related to movement of the stage in a second direction determined based on the first parameter, and
wherein a moving distance of the stage in the first direction is longer than a moving distance in the second direction.

15. An information processing apparatus comprising:
an information processing unit configured to determine a driving profile that is used to control movement of a stage configured to move while holding a substrate,
wherein the information processing unit determines:
a second parameter that is a parameter related to movement of the stage in a second direction in which a moving distance is shorter than a moving distance in a first direction based on a first parameter that is a parameter related to movement of the stage in the first direction; and
the driving profile based on the first parameter and the second parameter.

16. An information processing method for determining a driving profile that is used to control movement of a stage configured to move while holding a substrate, the information processing method comprising:
a first determination process for determining a second parameter that is a parameter related to movement of the stage in a second direction in which a moving distance is shorter than a moving distance in a first direction based on a first parameter that is a parameter related to movement of the stage in the first direction;
a second determination process for determining the driving profile based on the first parameter and the second parameter; and
a transmission process for transmitting the driving profile determined in the second determination process.

17. A non-transitory computer-readable storage medium storing a program for causing a computer to execute the information processing method according to claim 16.

18. A manufacturing method for an article, the manufacturing method comprising:
a first determination process for determining a second parameter that is a parameter related to movement of a stage in a second direction in which a moving distance is shorter than a moving distance in a first direction based on a first parameter that is a parameter related to movement of the stage configured to move while holding a substrate in the first direction;
a second determination process for determining a driving profile that is used to control movement of the stage based on the first parameter and the second parameter;
a forming process for forming a pattern on the substrate held by the stage while controlling movement of the stage based on the driving profile determined in the second determination process; and
a manufacturing process for manufacturing an article from the substrate on which the pattern is formed in the forming process.
